(19) United States
(12) Patent Application Publication
(10) Pub. No.: US 2021/0242765 A1
(43) Pub. Date: Aug. 5, 2021

(54) TRANSPORT SYSTEM, PROCESSING SYSTEM, AND ARTICLE MANUFACTURING METHOD

(71) Applicant: CANON KABUSHIKI KAISHA, Tokyo (JP)

(72) Inventors: Hitoshi Suzuki, Chiba (JP); Takeshi Yamamoto, Kanagawa (US)

(21) Appl. No.: 17/161,981

(22) Filed: Jan. 29, 2021

(30) Foreign Application Priority Data
Feb. 5, 2020 (JP) 2020-018350

(51) Int. Cl. H02K 41/03; H02K 11/21; C23C 16/54; C23C 14/56

(52) U.S. Cl. CPC H02K 41/031; C23C 14/56; C23C 16/54; H02K 11/21

(57) ABSTRACT

A transport system includes: a stator having coils each including a winding and a core; and a mover having magnets to move in the transport direction by electromagnetic force generated between the plurality of coils and the magnet, the stator and the mover have one and the other of first and second transport members, respectively, that guide the moving mover in the transport direction, the first transport member includes upper-side and lower-side transport members, a transport position of the mover is adjusted so that an upper face of at least one magnet is located below or above an equilibrium position where magnetic attractive force generated between the core and the magnet and gravity on the mover are balanced with each other, and the mover is transported in a state where the second transport member is in contact with the lower-side or upper-side transport member in accordance with the transport position.

### BACKGROUND OF THE INVENTION

### Field of the Invention

The present invention relates to a transport system, a processing system, and an article manufacturing method.

### Description of the Related Art

In general, a transport system is used in a production line used for assembling industry products, a semiconductor exposure apparatus, or the like. In particular, a transport system in a production line transports workpieces such as components between a plurality of stations within a factory-automated production line or between factory-automated production lines. Further, such a transport system may be used as a transport apparatus within a process apparatus. As a transport system, a transport system with a movable magnet type linear motor has already been proposed.

In the transport system with a movable magnet type linear motor, the transport system is configured using a guiding apparatus involving mechanical contact, such as a linear guide. In the transport system using a guiding apparatus such as a linear guide, however, there is a problem of deteriorated productivity caused by a contaminant generated from a sliding portion of the linear guide, for example, a wear piece or a lubricant oil of a rail or a bearing, a volatilized substance thereof, or the like. Further, there is a problem of shortened life of a linear guide due to increased friction of a sliding portion at high speed transportation.

Accordingly, Japanese Patent No. 5439762 and Japanese Patent Application Laid-Open No. 2000-24816 disclose an apparatus that cancels the self-weight applied on a movable portion or a moving member. The apparatus disclosed in Japanese Patent No. 5439762 has an auxiliary mechanism that applies magnetic force to a movable portion in a direction to cancel the self-weight of the movable portion working on a guide mechanism together with the guide mechanism that supports the movable portion and guides the motion of the movable portion. Further, the apparatus disclosed in Japanese Patent Application Laid-Open No. 2000-24816 has a guiding unit that guides a belt that connects and hangs a moving member that moves upward and downward along a linear traveling guide at one end and a weight having the same weight as the moving member at the other end.

### SUMMARY OF THE INVENTION

According to one aspect of the present invention, provided is a transport system including: a stator having a plurality of coils arranged along a transport direction, in which each of the plurality of coils includes a winding and a core; and a mover having a plurality of magnets arranged so as to face the plurality of coils and configured to move in the transport direction by electromagnetic force generated between the plurality of coils and the magnet. The stator has one of a first transport member and a second transport member that guide, in the transport direction, the mover that is moving. The first transport member includes an upper-side transport member and a lower-side transport member installed to be located above and below the second transport member, respectively. The mover has the other of the first transport member and the second transport member, and a transport position of the mover is adjusted so that an upper face of at least one magnet is located below or above an equilibrium position where magnetic attractive force generated between the core and the magnet and gravity working on the mover are balanced with each other. The mover is transported in a state where the second transport member is in contact with the lower-side transport member or the upper-side transport member in accordance with the transport position. j

According to another aspect of the present invention, provided is a transport system including: a stator having a plurality of coils arranged along a transport direction; and a mover having a plurality of magnets arranged so as to face the plurality of coils. The stator has one of a first transport member and a second transport member that guide, in the transport direction, the mover that is moving. The first transport member includes an upper-side transport member and a lower-side transport member installed to be located above and below the second transport member, respectively. The mover has the other of the first transport member and the second transport member, and the transport system further includes a control apparatus that supplies current to the coil, generates force in the direction to cancel the gravity working on the mover, causes the second transport member to press against the lower-side transport member or the upper-side transport member, and moves the mover in the transport direction.

Further features of the present invention will become apparent from the following description of exemplary embodiments with reference to the attached drawings.

### BRIEF DESCRIPTION OF THE DRAWINGS

FIG. 1 is a schematic diagram illustrating an overall configuration of a transport system including a carrier and a stator according to a first embodiment of the present invention when viewed from the Z direction.

FIG. 2 is a schematic diagram illustrating an overall configuration of the transport system including the carrier and the stator according to the first embodiment of the present invention when viewed from the Y direction.

FIG. 3A is a schematic diagram illustrating a control system in the transport system according to the first embodiment of the present invention.

FIG. 3B is a schematic diagram illustrating the control system in the transport system according to the first embodiment of the present invention.

FIG. 4A is a schematic diagram illustrating a configuration including the carrier and the stator in the transport system according to the first embodiment of the present invention when viewed from the X direction.

FIG. 4B is a schematic diagram illustrating a configuration including the carrier and the stator in the transport system according to the first embodiment of the present invention when viewed from the X direction.

FIG. 5A is a schematic diagram illustrating a position relationship between the carrier and the stator in the transport system according to the first embodiment of the present invention when viewed from the X direction.

FIG. 5B is a schematic diagram illustrating a position relationship between the carrier and the stator in the transport system according to the first embodiment of the present invention when viewed from the X direction.

FIG. 5C is a schematic diagram illustrating a position relationship between the carrier and the stator in the transport system according to the first embodiment of the present invention when viewed from the X direction.

FIG. 6A is a schematic diagram illustrating a configuration including a carrier and a stator in a transport system according to a second embodiment of the present invention when viewed from the X direction.

FIG. 6B is a schematic diagram illustrating a configuration including the carrier and the stator in the transport system according to the second embodiment of the present invention when viewed from the X direction.

FIG. 7 is a schematic diagram illustrating a configuration including a carrier and a stator in a transport system according to a fourth embodiment of the present invention when viewed from the X direction.

### DESCRIPTION OF THE EMBODIMENTS

In a conventional transport system, it is difficult to reduce a contaminant generated from a sliding portion of a mover or a stator without involving an increase in size or an increase in complexity of an apparatus.

For example, an apparatus disclosed in Japanese Patent No. 5439762 has an auxiliary mechanism that applies magnetic force to a movable portion separately from a linear actuator for canceling a self-weight. Since the auxiliary mechanism is separately included, it is difficult to prevent an increase in the apparatus size in the apparatus disclosed in Japanese Patent No. 5439762.

Further, in an apparatus disclosed in Japanese Patent Application Laid-Open No. 2000-24816, a moving member connected to a weight via a sliding belt stops in a state of being balanced with tensile force applied from the belt caused by the weight having the same weight as the self-weight of the moving member and moves in orthogonal direction in response to slight external force. In the apparatus disclosed in Japanese Patent Application Laid-Open No. 2000-24816, while it is possible to move the moving member by small friction force because the sliding belt is guided via gas, it is difficult to move the moving member in a direction other than the orthogonal direction due to restriction caused by the belt.

### First Embodiment

The first embodiment of the present invention will be described below with reference to the drawings.

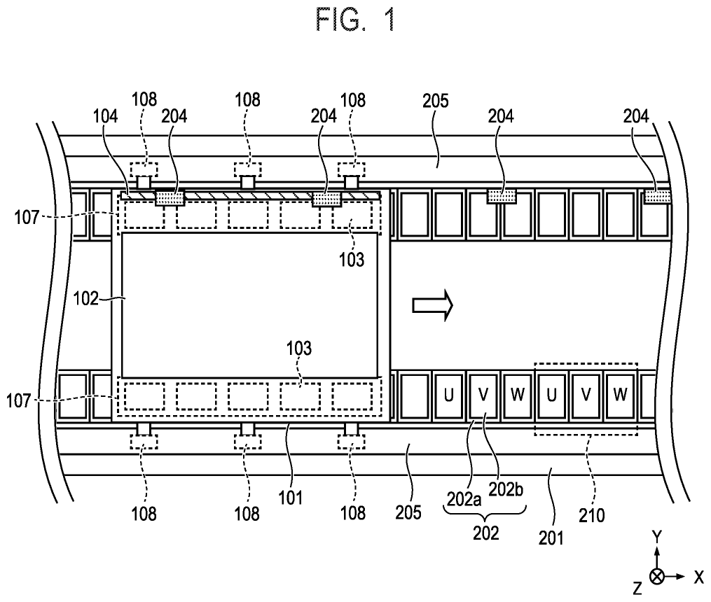

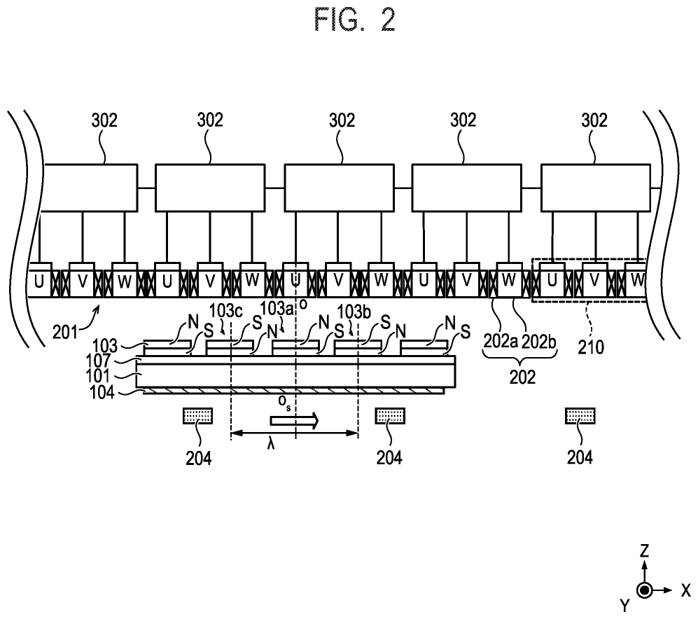

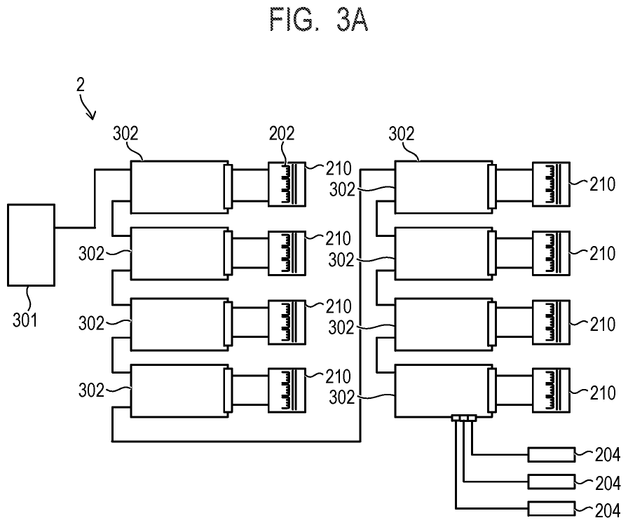

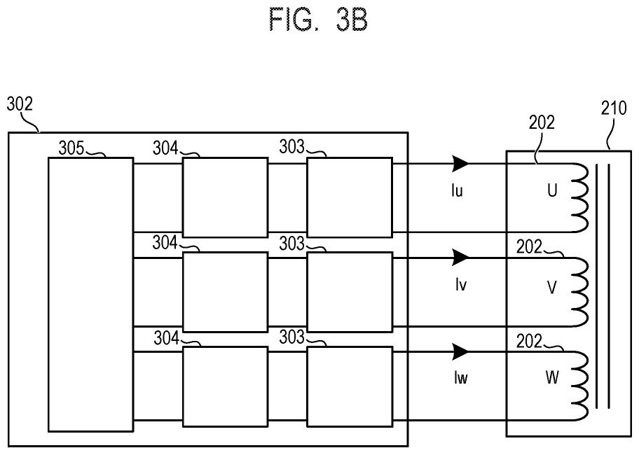

First, an overall configuration of a transport system according to the present embodiment will be described with reference to FIG. 1 to FIG. 3B. FIG. 1 is a schematic diagram illustrating an overall configuration of a transport system including a carrier and a stator according to the present embodiment when viewed from the Z direction described later. FIG. 2 is a schematic diagram illustrating an overall configuration of the transport system including the carrier and the stator according to the present embodiment when viewed from the Y direction described later. FIG. 3A and FIG. 3B are schematic diagrams illustrating a control system in the transport system according to the present embodiment. Note that FIG. 1 is a perspective view of a carrier 101 and a stator 201 when viewed from the lower side of the Z direction, and FIG. 2 is a sectional view of the carrier 101 and the stator 201 when viewed from the Y direction.

As illustrated in FIG. 1 and FIG. 2, a transport system 1 according to the present embodiment has the carrier 101 that is a mover and the stator 201 forming a transport path. The transport system 1 is a transport system formed of a movable magnet type linear motor (a moving permanent magnet type linear motor, a movable field magnet type linear motor). The transport system 1 forms a part of a processing system also having a process apparatus that performs processing on a workpiece 102 transported by the carrier 101.

The transport system 1 transports the workpiece 102 held on the carrier 101 to the process apparatus in which a processing operation is performed on the workpiece 102 by transporting the carrier 101 by the stator 201, for example. The process apparatus is not particularly limited and is, for example, or a film forming apparatus such as a vapor deposition apparatus or a sputtering apparatus to form a film on a glass substrate that is the workpiece 102. Note that, in FIG. 1 and FIG. 2, while a single carrier 101 is illustrated with respect to the stator 201, the embodiment is not limited thereto. In the transport system 1, a plurality of carriers 101 may be transported on the stator 201.

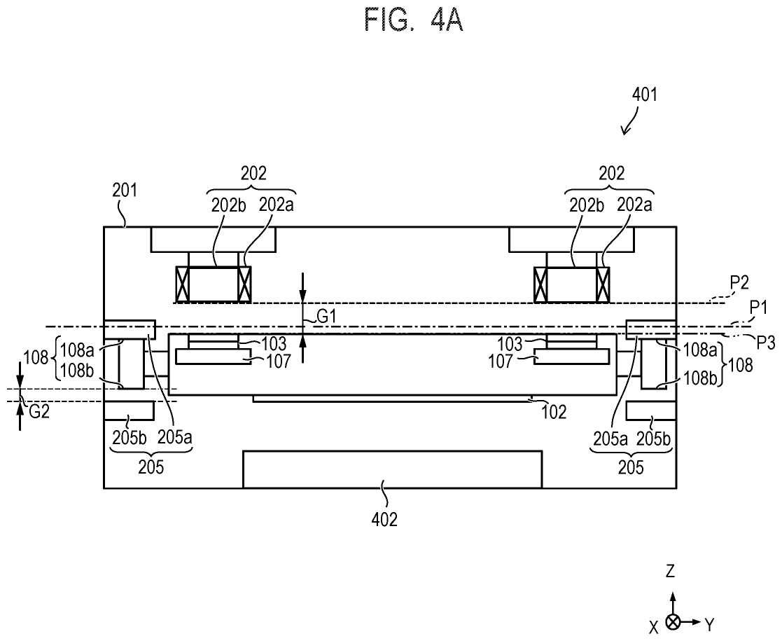

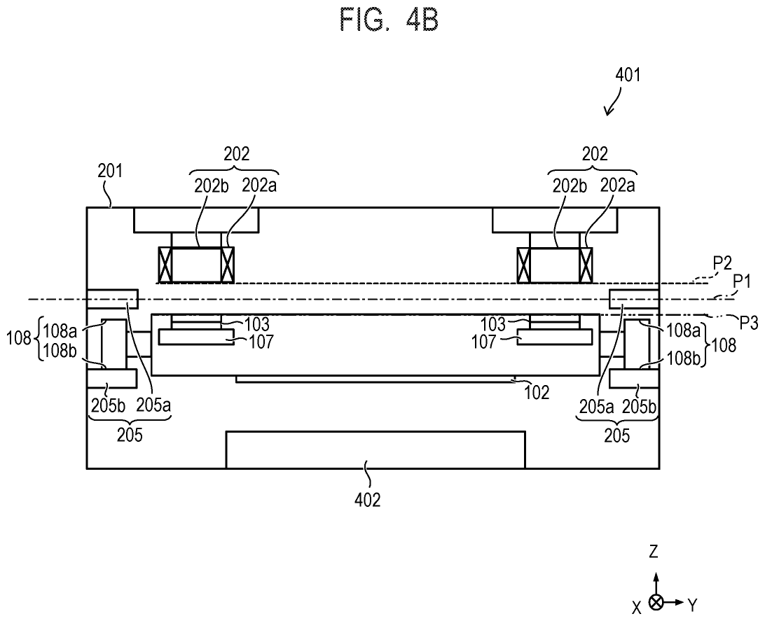

Herein, coordinate axes and directions used in the following description will be defined. In FIG. 1 and FIG. 2, an X-axis is taken along the horizontal direction that is the transport direction of the carrier 101, and the transport direction of the carrier 101 is defined as an X direction. Further, a Z-axis is taken along the perpendicular direction that is the direction orthogonal to the X direction, and the perpendicular direction is defined as a Z direction. Further, a Y-axis is taken along the direction orthogonal to the X direction and the Z direction, and a Y direction is defined as the direction orthogonal to the X direction and the Z direction. Note that, while it is not necessarily required that the transport direction of the carrier 101 is the horizontal direction, also in such a case, the Y direction and the Z direction can be similarly defined with the transport direction being defined as the X direction. Further, FIG. 4A to FIG. 7 will be described by using the same coordinate axes and the same directions.

The carrier 101 that is a mover movable in the X direction has at least one magnet 103 that is a permanent magnet, at least one scale 104, at least one yoke 107, and at least one rotary member 108 that is a transport member. On the other hand, the stator 201 has at least one coil 202, at least one encoder 204, and at least one auxiliary member 205 that is a transport member. The magnet 103 is not necessarily required to be a permanent magnet and may be any magnet. In other words, the magnet 103 includes a group of magnets formed of a plurality of magnets.

The plurality of magnets 103 are attached and installed on the top of the carrier 101 via the yoke 107. The yoke 107 is formed of a material having large magnetic permeability, for example, iron. The plurality of magnets 103 are installed to be arranged in two lines on both sides parallel to the X direction on the top of the carrier 101. The magnets 103 on each line are aligned in the X direction so that the polarities of the outer magnetic poles facing the stator 201 side are alternately different, respectively. In such a way, the plurality of magnets 103 are arranged to be able to face the plurality of coils 202 of the stator 201.

Each rotary member 108 is a transport member on the carrier 101 side for transporting the carrier 101 and specifically a wheel for the carrier 101 to travel on the stator 201 in the X direction. The plurality of rotary members 108 are attached and installed on both side portions parallel to the X direction of the carrier 101. When the carrier 101 travels in the X direction, the rotary member 108 rotates in contact with the auxiliary member 205 that is a transport member on the stator 201 side.

The scale 104 is fixed and installed along the X direction at a position that can be read by the encoder 204 of the stator 201.

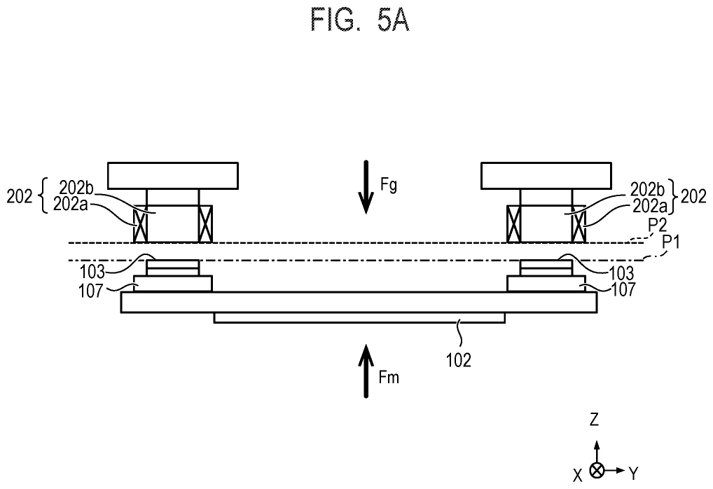

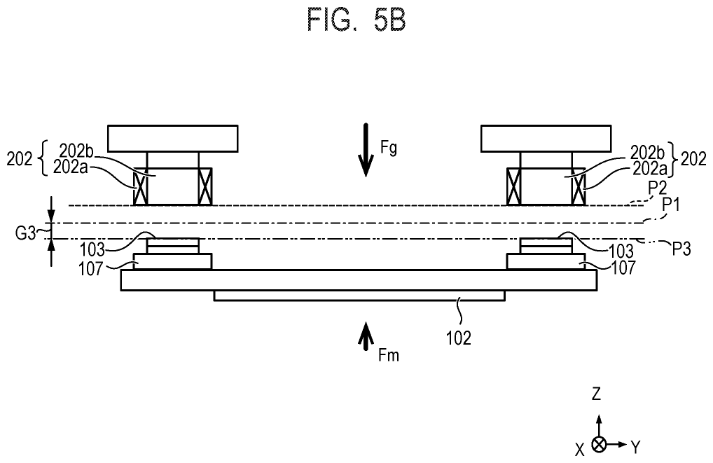

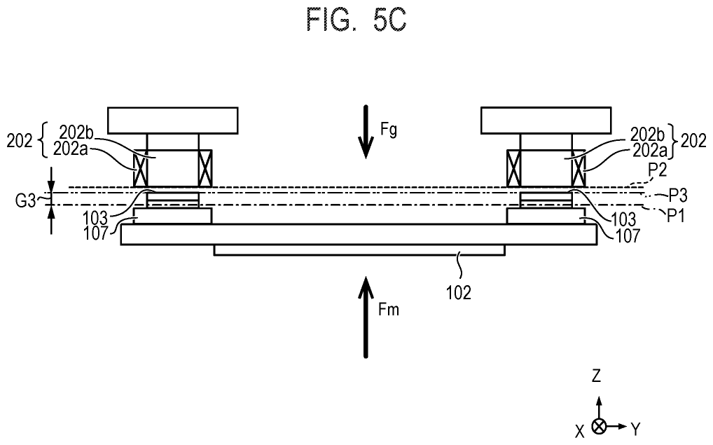

As described above, the carrier 101 in which the magnets 103 and the rotary members 108 are installed is configured to move and be transported in the X direction in response to electromagnetic force applied to the magnet 103 from the coil 202 of the stator 201. For example, the carrier 101 configured such that the workpiece 102 is attached to or held and transported by the upper side or the underside of the carrier 101. Note that FIG. 1, FIG. 4A to FIG. 5C illustrate a state where the workpiece 102 is attached under the carrier 101. Note that the mechanism for attaching or holding the workpiece 102 to the carrier 101 is not particularly limited, and a general attachment mechanism, a general holding mechanism, or the like such as a mechanical hook or an electrostatic chuck can be used.

In the stator 201, each encoder 204 is attached and installed so as to be able to read the scale 104 of the carrier 101. The encoder 204 can detect a relative position with respect to the encoder 204 of the carrier 101 by reading the scale 104 of the carrier 101. The plurality of encoders 204 are installed along the X direction. The plurality of encoders 204 are installed at intervals at which the position of one carrier 101 can be always detected by any one of the encoders 204 even when the carriers 101 are being transported. Each encoder 204 outputs position information indicating the relative position of the carrier 101 with respect to the encoder 204.

The plurality of coils 202 are attached and installed on the stator 201 so as to be able to face the magnets 103 of the carrier 101. The plurality of coils 202 are arranged so as to be able to face the magnets 103 of the carrier 101 from the top. Each of the plurality of coils 202 has a winding 202a and a core 202b around which the winding 202a is wound. The plurality of coils 202 are installed so as to be arranged in two lines on both sides parallel to the X direction so that the coils 202 can face the magnets 103 on the two lines of the carrier 101 from the top in the Z direction, respectively. On each line of the coil 202, the plurality of coils 202 are installed so that the coil units 210 in which three coils 202 of U-phase, V-phase, and W-phase are aligned in this order in the X direction are aligned in the X direction. When the coil unit 210 is defined as one unit, the plurality of coils 202 are controlled on a unit basis. When current is applied, the coil 202 generates attractive force or repulsive force caused by electromagnetic force with respect to the magnets 103 of the carrier 101 and thereby can apply force to the carrier 101. In such a way, in the stator 201, a transport path is formed on which the coil units 210 that can apply force to the carrier 101 are aligned along the X direction that is a transport direction of the carrier 101.

Each auxiliary member 205 is a transport member on the stator 201 side used for transporting the carrier 101, specifically, a rail-like member on which the rotary member 108 of the carrier 101 travels in contact therewith. The auxiliary member 205 is attached and installed to the stator 201 so as to be located on both sides of the carrier 101 parallel to the X direction so that the rotary members 108 of both side portions of the carrier 101 can travel. The auxiliary member 205 and the rotary member 108 are members that guide the moving carrier 101 in the X direction.

The auxiliary member 205 has an upper-side auxiliary member 205a that is an upper-side transport member and a lower-side auxiliary member 205b that is a lower-side transport member (see FIG. 4A and FIG. 4B). The upper-side auxiliary member 205a and the lower-side auxiliary member 205b are rail-like members at installation positions that vertically differ from each other. The upper-side auxiliary member 205a and the lower-side auxiliary member 205b are installed so as to be located above and under the rotary member 108 of the carrier 101, respectively. As described later, all or some of the plurality of rotary members 108 of the carrier 101 travel in contact with the lower-side auxiliary member 205b, which is one of the upper-side auxiliary member 205a and the lower-side auxiliary member 205b, between the upper-side auxiliary member 205a and the lower-side auxiliary member 205b.

Note that, in the present embodiment and the second to fourth embodiments described later, while a configuration in which the coil units 210, the magnets 103, the yokes 107, the rotary members 108, and the auxiliary members 205 are arranged symmetrically in two lines on both sides with respect to the transport direction is described, the embodiment is not limited thereto. The number of lines of the coil units 210, the number of lines of the magnets 103, the number of lines of the yokes 107, the number of lines of the rotary members 108, and the number of lines of the auxiliary members 205 may be one or may be plural. For example, the number of lines of each unit can be set in accordance with the size, the mass, or the like of the carrier 101, the workpiece 102, or the like.

The transport system 1 according to the present embodiment has a control system 2, as illustrated in FIG. 3A. The control system 2 has an integration controller 301 and coil controllers 302. Each coil controller 302 is provided for each coil unit 210. The coil controller 302 is connected to the integration controller 301 in a communicative manner. Note that the communication specification between the integration controller 301 and the coil controller 302 is not particularly limited, and general specification can be used. For example, the communication specification may be controller area network (CAN), Ethernet (registered trademark), Ethernet for control automation technology (EtherCAT), or the like.

A corresponding coil unit 210 is connected to each coil controller 302. Note that FIG. 3A illustrates the case where the coil 202 of each phase of the coil unit 210 formed such that three coils 202 of U-phase, V-phase, and W-phase are grouped as one unit is connected to the coil controller 302 one by one as an example. Further, the encoders 204 are connected to the coil controller 302.

Position information related to the carrier 101 output from the encoder 204 is transmitted to the integration controller 301via the coil controllers 302. The integration controller 301 calculates the position of the carrier 101 on the transport path in the stator 201 based on the position information obtained from the encoder 204 and controls transport of the carrier 101. The integration controller 301 transmits the calculated position information indicating the position of the carrier 101 to the coil controllers 302.

Each coil controller 302 detects the level of each current that flows in each coil 202 of the connected coil unit 210 and controls each current. The coil controller 302 calculates a current value instruction indicating a target current value in accordance with the position information indicating the position of the carrier 101 and controls a current value of current that flows in each coil 202 of the connected coil unit 210.

As illustrated in FIG. 3B, the coil controller 302 has current detection units 303 each configured to detect current of the coil 202, current control units 304 each configured to control the current of the coils 202, and current calculation units 305 each configured to calculate the current of the coils 202. The current detection unit 303 is provided between the current control unit 304 and the coil 202. The current control unit 304 is connected to the current calculation unit 305.

The current detection unit 303 detects current that flows between the current control unit 304 and the coil 202. The current detection unit 303 can detect current that flows in the direction from the current control unit 304 to the coil 202 as positive current. The current detection unit 303 inputs information related to the detected current to the current calculation unit 305.

The current calculation unit 305 calculates a current value to flow through each coil 202 of the coil unit 210 based on the position information transmitted from the integration controller 301 and information related to current input from the current detection unit 303. The current calculation unit 305 inputs the calculated current value to the current control unit 304.

The current control unit 304 controls current that flows in each coil 202 based on the current value input from the current calculation unit 305. Here, when current values flowing in respective coils 202 of U-phase, V-phase, and W-phase are denoted as Iu, Iv, and Iw, respectively, the current Iu, Iv, and Iw are controlled by the current control unit 304 so that the relationship of the following Equation (1) is met.

Iu+Iv+Iw=0 (1)

Note that, although FIG. 3B illustrates the case where the coils 202 are individually connected to the coil controllers 302, the coils 202 may be connected to the coil controllers 302 with star connection or the like used in a general three-phase motor.

Next, a position of the carrier 101 transported in the transport system 1 according to the present embodiment in the Z direction will be further described with reference to FIG. 4A to FIG. 5C. FIG. 4A and FIG. 4B are schematic diagrams illustrating a configuration including the carrier 101 and the stator 201 in the transport system 1 according to the present embodiment when viewed from the X direction. FIG. 5A to FIG. 5C are schematic diagrams illustrating a position relationship of the carrier 101 and the stator 201 in the transport system 1 according to the present embodiment when viewed from the X direction.

FIG. 4A is a sectional view illustrating an adjustment position that is a position of the carrier 101 in the Z direction adjusted before the carrier 101 is transported. On the other hand, FIG. 4B is a sectional view illustrating a transport position that is a position of the carrier 101 in the Z direction when the carrier 101 is transported in the X direction.

As illustrated in FIG. 4A and FIG. 4B, the auxiliary members 205 of the stator 201 are installed so as to be located on both sides of the carrier 101, respectively. Each auxiliary member 205 has the upper-side auxiliary member 205a that is an upper-side transport member located on the upper side and the lower-side auxiliary member 205b that is a lower-side transport member located below the upper-side auxiliary member 205a.

The rotary members 108 installed in both side portions of the carrier 101 are located between the upper-side auxiliary member 205a and the lower-side auxiliary member 205b in the auxiliary member 205 on the same side, respectively. The carrier 101 is transported in a state where the position thereof in the Z direction is adjusted as described later.

Note that FIG. 4A and FIG. 4B illustrate a case where the carrier 101 and the stator 201 are embedded in a chamber of a vapor deposition apparatus 401 that is an example of a process apparatus to perform a processing operation on the workpiece 102. In the lower portion in the chamber of the vapor deposition apparatus 401, a vapor deposition source 402 is installed. On a substrate that is the workpiece 102 attached to the lower portion of the carrier 101 transported to the installation position of the vapor deposition source 402, a thin film such as a metal or an oxide is formed by vapor deposition by the vapor deposition source 402. As described above, the carrier 101 and the workpiece 102 are transported, a process apparatus performs processing on the transported workpiece 102, and an article is manufactured.

The position of the carrier 101 in the Z direction differs in accordance with the relationship between magnetic attractive force, which is generated between the magnet 103 and the core 202b, and the gravity working on the carrier 101. FIG. 5A to FIG. 5C are sectional views illustrating a position relationship of the carrier 101 and the stator 201 in the Z direction when viewed from the X direction. As illustrated in FIG. 5A to FIG. 5C, between the core 202b of the coil 202 and the magnet 103, that is, between the core 202b of the coil 202 and the magnet 103, the magnetic attractive force Fm is generated in the perpendicular direction. Further, the gravity Fg works on the carrier 101 in the perpendicular direction.

FIG. 5A illustrates a state where the carrier 101 is arranged at a position where the magnetic attractive force Fm and the gravity Fg are balanced with each other. In FIG. 5A, a surface on the carrier 101 side of the coil 202, specifically, a position P2 of the surface on the carrier 101 side of the core 202b in the Z direction is indicated by a dashed line as a reference. Further, a position of the top faces of the magnets 103 in the Z direction when the magnetic attractive force Fm and the gravity Fg are balanced with each other is indicated by the one-dot-dashed line as an equilibrium position P1. Note that FIG. 4A and FIG. 4B illustrate the equilibrium position P1 and the position P2 in the same manner.

FIG. 5B illustrates a state where a position P3 of the top faces of the magnets 103 in the Z direction is below the equilibrium position P1 in the perpendicular direction, and the gravity Fg is larger than the magnetic attractive force Fm. In such a case, in the Z direction, a gap G3 between the equilibrium position P1 and the position P3 of the top faces of the magnets 103 is formed on the opposite side of the coil 202 with respect to the equilibrium position P1. Note that, in FIG. 5B and FIG. 5C, the position P3 is indicated by a two-dot chain line. FIG. 4A and FIG. 4B illustrate the position P3 in the same manner.

FIG. 5C illustrates a state where the position P3 of the top faces of the magnets 103 in the Z direction is above the equilibrium position P1 in the perpendicular direction, and the gravity Fg is smaller than the magnetic attractive force Fm. In such a case, in the Z direction, the gap G3 between the equilibrium position P1 and the position P3 of the top faces of the magnets 103 is formed on the coil 202 side with respect to the equilibrium position P1.

In general, if it is possible to increase magnetic attractive force and repulsive force generated between the coil 202 and the magnet 103, it is possible to increase thrust of a linear motor that transports the carrier 101. Since magnetic attractive force and repulsive force change in accordance with the magnitude of magnetic flux density in the gap between the coil 202 and the magnet 103, an increase in the magnetic flux density increases the magnetic attractive force. To increase the magnetic flux density in the gap, it is considered to select a strong magnet such as a neodymium magnet and a samarium-cobalt magnet as the magnet 103. Further, an increase in the volume of the magnet 103 can increase the magnetic flux density in the gap. Further, in the coil 202, when the core 202b having high magnetic permeability is arranged at the center of the winding 202a, this can increase the magnetic flux density. The core 202b having high magnetic permeability has small magnetic resistance and is likely to pass through the magnetic flux. By arranging the core 202b in the winding, the core 202b in the winding, since this facilitates magnetic flux generated from the magnet 103 to pass through the coil 202, it is possible to increase the magnetic flux density in the gap. Moreover, by arranging the magnet 103 and the core 202b so that the respective centers are substantially the same in the Z direction, this facilitates the magnetic flux to pass through, and as a result, it is possible to generate force between the coil 202 and the magnet 103 efficiently.

On the other hand, when a member having high magnetic permeability is present around the magnet 103, attractive force is generated between the magnet 103 and the member having high magnetic permeability. That is, the attractive force of the magnet 103 also works on the core 202b of the coil 202 arranged near the magnet 103. For example, in a case of a configuration in which the core 202b and the magnet 103 are close to each other, attractive force works, and large force is applied to the rotary member 108 or the auxiliary member 205. In a configuration in which both the core 202b and the magnet 103 are close to each other, it is required that the rotary member 108 or the auxiliary member 205 have strength enough to avoid deformation or breakage due to attractive force. In a configuration in which the core 202b and the magnet 103 are apart from each other, in particular when the carrier 101 has a large weight, it is required that the rotary member 108 or the auxiliary member 205 that supports the carrier 101 has strength enough to avoid deformation or breakage due to the gravity.

As an example, the attractive force when the material of the magnet 103 is a neodymium magnet, the size of the magnet 103 is 50×40×10 mm, and the magnet 103 is attached to the yoke 107 is several hundred Newtons when a gap between the core 202b and the magnet 103 is 1 mm. Moreover, when the plurality of magnets 103 are arranged on the carrier 101, attractive force obtained by multiplying the above attractive force by the number of magnets 103 will be applied to the carrier 101.

When the strength of the rotary member 108 or the auxiliary member 205 is insufficient, the carrier 101 or the stator 201 is deformed due to the attractive force or the gravity, and contact or rubbing occurs between the carrier 101 and the peripheral member after the deformation. Further, attempt to ensure the strength of the rotary member 108 or the auxiliary member 205 may increase the size of each component and thus increase the size of the overall transport system 1. Even if the strength is ensured, when the carrier 101 is transported, a problem of an increase in the amount of debris that is a contaminant in the sliding portions of the rotary member 108 or the auxiliary member 205 that supports the carrier 101 arises as a result of application of large force thereto.

In the present embodiment, as illustrated in FIG. 5A, the equilibrium position P1 where the magnetic attractive force Fm generated between the cores 202b in the coils 202 and the magnets 103 and the gravity Fg working on the carrier 101 are balanced with each other is found, and the transport position of the carrier 101 is determined by using the equilibrium position P1 as a reference.

The equilibrium position P1 is a position of the top faces of the magnets 103 in a state where the magnetic attractive force Fm generated by the core 202b and the magnet 103 being faced with each other and the gravity Fg are balanced with each other. The equilibrium position P1 reflects the relative positional relationship in the perpendicular direction (Z direction) between the respective faces of the core 202b and the magnet 103 facing each other. Note that the magnetic attractive force Fm is the sum of the magnetic attractive force generated between the plurality of cores 202b and the plurality of magnets 103. The equilibrium position P1 is a position to the top faces of the magnets 103 when the magnetic attractive force Fm and the gravity Fg working on the carrier 101 are balanced with each other by using the position P2 of the bottom faces of the cores 202b as a reference.

An example of a procedure to find the equilibrium position P1 that is a reference for determining the transport position of the carrier 101 will be described.

First, in a state illustrated in FIG. 4A, a moderately inflated air jack is arranged between the magnets 103 and the cores 202b in advance. Further, the upper-side auxiliary member 205a is detached from the stator 201 in advance. The position of the carrier 101 at this time is a position where the gravity Fg is larger than the magnetic attractive force Fm, that is, a position where the position P3 of the top faces of the magnets 103 is lower than the equilibrium position P1.

Next, the carrier 101 is lifted to the core 202b side along the Z direction. When the carrier 101 is lifted so that the top faces of the magnets 103 are located above the equilibrium position P1, magnetic attractive force works between the cores 202b and the magnets 103, and the carrier 101 is attracted to the core 202b side due to the magnetic attractive force.

When the carrier 101 is attracted to the core 202b side, since a space occurs between the cores 202b and the magnets 103 by the air jack, a spacer is arranged in the space. The spacer may be made of any material having no magnetic property, such as a resin. Herein, a force sensor such as a force gauge or a load cell is installed on the spacer in advance. The force sensor is arranged to be able to measure force in the perpendicular direction (Z direction). The force sensor measures the sum of the gravity Fg working on the carrier 101 and the magnetic attractive force generated between the cores 202b and the magnets 103.

As described above, the air jack is deflated in a state where the space including the force sensor is arranged. Then, since the carrier 101 is attracted to the core 202b side while interposing the spacer and the force sensor, it is possible to measure the sum of the gravity Fg and the magnetic attractive force Fm by the force sensor. In such a way, the carrier 101 is temporarily positioned in the Z direction, and the sum of the gravity Fg and the magnetic attractive force Fm is measured.

While the position of the carrier 101 is changed in the order from the position close to the core 202b to the position far from the core 202b, the measurement is performed by the force sensor at each position to search for the position of the equilibrium position P1. At a position close to the core 202b, since the distance between the core 202b and the magnet 103 is small, the magnetic attractive force Fm is measured to be large. With gradual increase of the thickness of the spacer and repetition of the above procedure to perform measurement at each position by using the force sensor, the measured value of the force sensor gradually approaches 0 Newton. The position of the top faces of the magnets 103 when the measured value of the force sensor becomes 0 Newton is defined as the equilibrium position P1. In such a way, the equilibrium position P1 can be found.

Note that, even when another member is interposed between the core 202b and the magnet 103, it is possible to find the equilibrium position P1. For example, it is considered that some coils 202 are stored in one box and collectively arranged in order to improve working efficiency. In such a case, a part of the box in which the coil 202 is stored is interposed between the core 202b and the magnet 103. Further, for example, a case where the magnets 103 are arranged inside the carrier 101 is considered. In such a case, a part of the casing of the carrier 101 is present between the core 202b and the magnet 103. Even in these cases, the same consideration may apply if the equilibrium position P1 is searched for by the above procedure between a member including the cores 202b and the carrier 101 including the magnets 103 and the distance from the other members to the cores 202b or the magnets 103 is subtracted therefrom.

Further, although the example using an air jack, a spacer, and a force sensor has been illustrated as a procedure to find the equilibrium position P1 in the above description, the procedure is not limited thereto. Various procedures can be used as long as the equilibrium position P1 where the sum of magnetic attractive force Fm and the gravity Fg is 0 Newton in the Z direction can be found by the procedure.

The following position is considered as a transport position to which the carrier 101 is transported with respect to the equilibrium position P1 described above. That is, the transport position of the carrier 101 may be a position where the position P3 of the top faces of the magnets 103 in the Z direction is closer to the cores 202b than to the equilibrium position P1, a position where the position P3 matches the equilibrium position P1, or a position where the position P3 is farther from the core 202b than from the equilibrium position P1.

When the carrier 101 is transported at a position where the position P3 is closer to the cores 202b than to the equilibrium position P1, for example, the carrier 101 is tilted for stepping over a level difference, a part of the carrier 101 may come excessively closer to and then attach to the cores 202b due to magnetic attractive force. In such a case, if the carrier 101 is being transported, the magnet 103 may be damaged by impact at attachment. Further, the coils 202 may be damaged by continuous flow of large current in the coils 202 attached with the carrier 101 and unable to move due to strong magnetic attractive force.

Further, as described above, magnetic attractive force generated between the magnets 103 and the cores 202b is significantly large. In particular, when the large carrier 101 is transported, the number of magnets 103 increases in order to obtain the thrust required in the transport direction. A greater number of magnets 103 makes it more difficult to remove the carrier 101 from the cores 202b in the attached state.

Further, if the carrier 101 is transported at a position where the position P3 matches the equilibrium position P1, the direction of the force applied to the carrier 101 in the Z direction changes due to variation of components or variation of assembly of components or the like. As a result, the position of the carrier 101 becomes unstable. Since the position becomes unstable, this causes unsteadiness during transportation of the carrier 101.

On the other hand, when the position P3 of the top faces of the magnets 103 is lowered away from the equilibrium position P1, this reduces the effect of reduction of the self-weight of the carrier 101 by using the magnetic attractive force Fm. In addition, the magnetic flux from the coil 202 is less likely to work on the magnet 103, and as a result, thrust in the transport direction will decrease.

Accordingly, the transport system 1 according to the present embodiment employs the configuration having the rotary member 108 that is installed to the carrier 101 and the auxiliary member 205 that receives the rotary member 108 on the stator 201 side. Further, in the present embodiment, as illustrated in FIG. 4A, the maximum gap G2 formed between the bottom 108b of the rotary member 108 and the lower-side auxiliary member 205b is set to be smaller than the gap G1 formed between the cores 202b and the magnets 103 in the Z direction. That is, the position of the carrier 101 including the rotary members 108 and the position of the auxiliary members 205 are adjusted with respect to the cores 202b such that the maximum gap G2 is smaller than the gap G1. The maximum gap G2 is a gap between the bottom 108b of the rotary member 108 and the lower-side auxiliary member 205b when the top 108a of the rotary member 108 whose motion to the coils 202 side is restricted by the upper-side auxiliary member 205a comes into contact with the upper-side auxiliary member 205a. Since the maximum gap G2 is smaller than the gap G1, the magnets 103 of the transported carrier 101 will not attract to the cores 202b of the coils 202.

Further, in the present embodiment, the position of the carrier 101 including the rotary members 108 and the position of the auxiliary members 205 are adjusted with respect to the cores 202b such that the position P3 of the top faces of the magnets 103 is below the equilibrium position P1 even at a position where the carrier 101 is the closest to the cores 202b. The position where the carrier 101 is the closest to the cores 202b is a position where the tops 108a of the rotary members 108 come into contact with the upper-side auxiliary members 205a.

In the present embodiment, since the gravity Fg is larger than the magnetic attractive force Fm, the bottoms 108b of the rotary members 108 of the carrier 101 come into contact with the lower-side auxiliary members 205b during transportation of the carrier 101. The carrier 101 is transported so as to travel in the X direction while the bottoms 108b of the rotary members 108 are in contact with the lower-side auxiliary members 205b due to electromagnetic force working between the coil 202 and the magnet 103.

In such a way, in the present embodiment, the transport position of the carrier 101 is adjusted such that the top faces of the magnets 103 are located below the equilibrium position P1.

In the transport system 1 according to the present embodiment having the configuration described above, since the magnetic attractive force Fm working on the carrier 101 always works in the opposite direction relative to the gravity Fg working on the carrier 101, it is possible to reduce the self-weight of the carrier 101. Since the magnetic attractive force Fm generated between the core 202b and the magnet 103 is used, it is possible to reduce the self-weight of the carrier 101 without involving an increase in size or an increase in complexity of the apparatus. Since the self-weight of the carrier 101 is reduced and the force applied to the rotary member 108 and the auxiliary member 205 can thus be reduced, debris such as a contaminant generated from a sliding portion between the rotary member 108 and the auxiliary member 205 can be reduced.

In the present embodiment, since the same coil 202 as the coil used for transporting the carrier 101 is used for reducing the self-weight of the carrier 101, neither increase in size nor an increase in complexity of the apparatus is involved for reducing the self-weight of the carrier 101. Further, in the present embodiment, in the direction orthogonal to the transport direction of the carrier 101 and the other direction crossing the transport direction of the carrier 101, there is no member that needs contact with other members, such as a belt that hangs the carrier 101. Thus, in the present embodiment, it is possible to easily move the carrier 101 in the X direction that is a transport direction.

Further, there may be a level difference due to a joint or the like on the auxiliary member 205 on which the rotary member 108 travels. In the present embodiment, since the self-weight of the carrier 101 is reduced, even when there is a level difference on the auxiliary member 205, it is possible to reduce an impact on the carrier 101 when the rotary member 108 passes through the level difference.

Further, in the present embodiment, since the motion of the rotary members 108 to the coils 202 side is restricted by the upper-side auxiliary members 205a, a state where a certain distance is secured between the core 202b and the magnet 103 is ensured even with any state of the carrier 101. For example, even when the large carrier 101 on which many magnets 103 are installed approaches the cores 202b side, since a state where the certain distance is secured is ensured, the magnetic attractive force will not become extremely large. In such a way, in the present embodiment, a state where a certain distance is secured between the core 202b and the magnet 103 is ensured, and therefore the magnetic attractive force occurring between the core 202b and the magnet 103 will not become extremely large. Thus, according to the present embodiment, it is possible to easily perform maintenance of the transport system 1 including the carrier 101 and the stator 201.

Further, to increase traveling performance of the carrier 101, a plurality of rotary members 108 may be installed in the carrier 101. In the present embodiment, all or some of the rotary members 108 are in contact with the auxiliary members 205 during transportation. That is, all or some of the plurality of rotary members 108 of the carrier 101 travel while being in contact with each lower-side auxiliary member 205b, which is one of the upper-side auxiliary member 205a and the lower-side auxiliary member 205b, between the upper-side auxiliary members 205a and the lower-side auxiliary members 205b. Thus, in the present embodiment, oscillation is less likely to occur in the control, and as a result, it is possible to improve response by increasing the gain.

As described above, according to the present embodiment, it is possible to reduce a contaminant generated from a sliding portion of the carrier 101 or the stator 201 without involving an increase in size or an increase in complexity of the apparatus.

### Second Embodiment

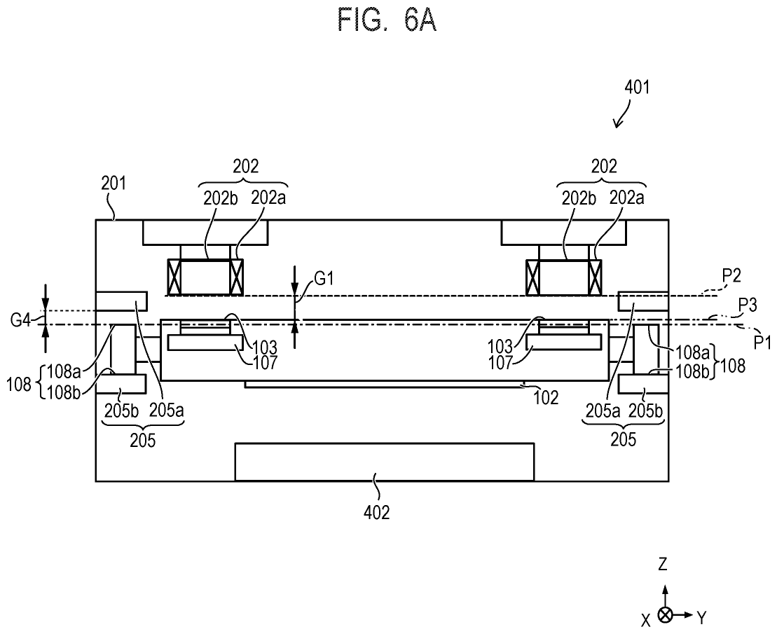

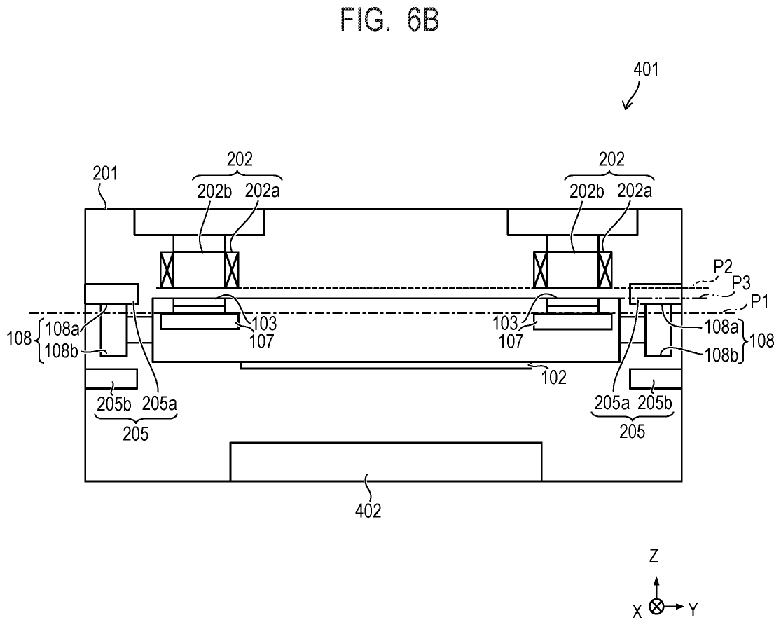

A second embodiment of the present invention will be described with reference to FIG. 6A and FIG. 6B. FIG. 6A and FIG. 6B are schematic diagrams illustrating a configuration including the carrier 101 and the stator 201 in the transport system 1 according to the present embodiment when viewed from the X direction. Note that the same components as those in the first embodiment described above are labeled with the same references, and the description thereof will be omitted or simplified.

The basic configuration of the transport system 1 according to the present embodiment is the same as the configuration of the transport system 1 according to the first embodiment illustrated in FIG. 1 to FIG. 4B. The transport system 1 according to the present embodiment differs from the transport system 1 according to the first embodiment in the feature of the position in the Z direction of the carrier 101 to be transported.

FIG. 6A is a sectional view illustrating an adjustment position that is a position in the Z direction of the carrier 101 adjusted prior to transport of the carrier 101 in the present embodiment. On the other hand, FIG. 6B is a sectional view illustrating a transport position that is a position in the Z direction of the carrier 101 when the carrier 101 is transported along the X direction in the present embodiment.

First, an example of a procedure to find the equilibrium position P1 in the present embodiment will be described. First, in the state illustrated in FIG. 6A, a moderately inflated air jack is arranged between the magnets 103 and the cores 202b in advance. At this time, the position of the carrier 101 is a position where the magnetic attractive force Fm is larger than the gravity Fg, that is, a position where the position P3 on the top faces of the magnets 103 is above the equilibrium position P1.

Next, after the carrier 101 is lifted and attracted to the cores 202b side along the Z direction, the lower-side auxiliary members 205b are removed. Herein, a position adjustment mechanism may be provided in the perpendicular direction (Z direction) to the lower-side auxiliary members 205b, and the carrier 101 may be ready to move so that the position P3 on the top faces of the magnets 103 comes below the equilibrium position P1. According to such a position adjustment mechanism, it is possible to prevent the position of the top faces of the magnets 103 from being lower than the position of the equilibrium position P1 and thus prevent the carrier 101 from dropping during adjustment.

Next, in the same manner as in the first embodiment, while the air jack and the spacer are used to perform temporarily positioning, a force sensor such as a force gate is used to measure the sum of the gravity Fg working on the carrier 101 in the perpendicular direction and the magnetic attractive force Fm occurring between the core 202b and the magnet 103. With gradual increase of the thickness of the spacer and repetition of the above procedure to perform measurement at each position by using the force sensor, the measured value of the force sensor gradually approaches 0 Newton. The position of the top faces of the magnets 103 when the measured value of the force sensor becomes 0 Newton is defined as the equilibrium position P1. In such a way, the equilibrium position P1 can be found also in the present embodiment.

Note that, when another member is interposed between the core 202b and the magnet 103, the same consideration as the first embodiment may apply also for the present embodiment.

Further, although the example using an air jack, a spacer, and a force sensor has been illustrated as a procedure to find the equilibrium position P1 also in the present embodiment, various procedures may be used in the same manner as in the first embodiment.

When transported at a distant position from the cores 202b, the carrier 101 is sometimes unable to step over a small level difference because of shortage of thrust, for example. If the carrier 101 is being transported, continuous flow of large current in the coils 202 for allowing the carrier 101 to step over a level difference may damage the coils 202.

Accordingly, the transport system 1 according to the present embodiment employs the configuration having the rotary member 108 that is installed to the carrier 101 and the auxiliary member 205 that receives the rotary member 108 on the stator 201 side in the same manner as in the first embodiment. Further, in the present embodiment, as illustrated in FIG. 6A, the maximum gap G4 formed between the top 108a of the rotary member and the upper-side auxiliary member 205a is set to be smaller than the gap G1 formed between the core 202b and the magnet 103 in the Z direction. That is, the position of the carrier 101 including the rotary members 108 and the position of the auxiliary members 205 are adjusted with respect to the cores 202b such that the maximum gap G4 is smaller than the gap G1. The maximum gap G4 is a gap between the top 108a of the rotary member 108 and the upper-side auxiliary member 205a when the bottom 108b of the rotary member 108 whose motion to the opposite side of the coils 202 is restricted by the lower-side auxiliary member 205b comes into contact with the lower-side auxiliary member 205b. Since the maximum gap G4 is smaller than the gap G1, the magnets 103 of the transported carrier 101 will not attract to the cores 202b of the coils 202.

Further, in the present embodiment, the position of the carrier 101 including the rotary members 108 and the position of the auxiliary members 205 are adjusted with respect to the cores 202b such that the position P3 of the top face of the magnets 103 is above the equilibrium position P1 even at a position where the carrier 101 is the furthest from the cores 202b. The position where the carrier 101 is the furthest from the cores 202b is a position where the bottoms 108b of the rotary members 108 come into contact with the lower-side auxiliary members 205b.

In the present embodiment, since the magnetic attractive force Fm is larger than the gravity Fg, the tops 108a of the rotary members 108 of the carrier 101 comes into contact with the upper-side auxiliary members 205a during transportation of the carrier 101. The carrier 101 is transported so as to travel in the X direction while the tops 108a of the rotary members 108 are in contact with the upper-side auxiliary members 205a due to electromagnetic force working between the coil 202 and the magnet 103.

In such a way, in the present embodiment, the transport position of the carrier 101 is adjusted such that the top faces of the magnets 103 are located above the equilibrium position P1.

In the transport system 1 according to the present embodiment having the configuration described above, the magnetic attractive force Fm working on the carrier 101 always works in the opposite direction relative to the gravity Fg working on the carrier 101. Moreover, the magnetic attractive force Fm is larger than the gravity Fg in the present embodiment. Thus, in the present embodiment, the self-weight of the carrier 101 can be cancelled. Also in the present embodiment, since the magnetic attractive force Fm generated between the core 202b and the magnet 103 is used in the same manner as in the first embodiment, it is possible to cancel the self-weight of the carrier 101 without involving an increase in size or an increase in complexity of the apparatus. Since the self-weight of the carrier 101 is cancelled and force applied to the rotary member 108 and the auxiliary member 205 can be reduced, debris that is a contaminant generated from a sliding portion between the rotary member 108 and the auxiliary member 205 can be reduced.

Further, in the present embodiment, since the self-weight of the carrier 101 is cancelled, even when there is a level difference on the auxiliary member 205, it is possible to reduce an impact on the carrier 101 when the rotary member 108 passes through the level difference in the same manner as in the first embodiment.

Further, also in the present embodiment, a state where a certain distance is secured between the core 202b and the magnet 103 by the upper-side auxiliary members 205a is ensured in the same manner as in the first embodiment. Accordingly, since the magnetic attractive force generated between the core 202b and the magnet 103 will not become extremely large, it is possible to easily perform maintenance of the transport system 1 including the carrier 101 and the stator 201.

Further, in the present embodiment, since the motion of the rotary members 108 to the opposite side of the coils 202 is restricted by the lower-side auxiliary members 205b, the position of the carrier 101 is within a range of a certain distance from the coils 202 even when the carrier 101 moves away from the cores 202b. Therefore, in the present embodiment, there is no shortage of thrust in the transport direction of the carrier 101.

Further, also in the present embodiment, when a plurality of rotary members 108 are installed to the carrier 101, all or some of the rotary members 108 are in contact with the auxiliary members 205 during transportation in the same manner as in the first embodiment. That is, all or some of the plurality of rotary members 108 of the carrier 101 travel while being in contact with each upper-side auxiliary member 205a, which is the other of the upper-side auxiliary member 205a and the lower-side auxiliary member 205b, between the upper-side auxiliary members 205a and the lower-side auxiliary members 205b. Thus, according to the present embodiment, it is possible to improve response by increasing the gain.

As described above, according to the present embodiment, it is possible to reduce a contaminant generated from a sliding portion between the carrier 101 and the stator 201 without involving an increase in size or an increase in complexity of the apparatus.

### Third Embodiment

A third embodiment of the present invention will be described. Note that the same components as those in the first and second embodiments described above are labeled with the same references, and the description thereof will be omitted or simplified.

The basic configuration of the transport system 1 according to the present embodiment is the same as the configuration of the transport system 1 according to the first or second embodiment illustrated in FIG. 1 to FIG. 6B.

In the present embodiment, a case of transporting the carrier 101 by using a plurality of coils 202 of the coil units 210 to applying force in the X direction and the Z direction against the magnets 103 on the carrier 101 in the configuration of the first or second embodiment will be described. The force in the X direction and the Z direction applied to the magnets 103 by using a plurality of coils 202 of the coil units 210 is electromagnetic force generated by an interaction of current flowing in the coils 202 and a magnetic field generated by the magnets 103, respectively.

Symbols used in the following description are defined here. The symbol Iu denotes U-phase current flowing in the coil unit 210. The symbol Iv denotes V-phase current flowing in the coil unit 210. The symbol Iw denotes W-phase current flowing in the coil unit 210. The symbol Q denotes the position in the X direction of the carrier 101. The symbol (Iu, Iv, Iw) denotes a current vector having elements of Iu, Iv, and Iw. The symbol “” denotes a multiplication symbol.

As illustrated in FIG. 2, the center Os in the X-axis direction of the carrier 101 is defined as the origin. Further, the three magnets 103 aligned in the order in the X direction are distinguished by denoting “magnet 103c”, “magnet 103a”, and “magnet 103b” if necessary. The center of the magnet 103a is located at the origin (center) Os. The distance between the center of the magnet 103b and the center of the magnet 103c in the X direction is denoted as λ. The center of the magnet 103b in the X direction is located at +λ/2 with respect to the origin Os as a reference in the X direction. The center of the magnet 103c in the X direction is located at −λ/2 with respect to the origin Os as a reference in the X direction.

Further, when the origin of the transport path with the stator 201 is denoted as O, the origin O is located at the center of the coil 202. FIG. 2 schematically illustrates a state where the center Os of the carrier 101 matches the origin O of the transport path.

Furthermore, symbols used in the following description will be defined here. The symbol Iq denotes q-axis current that is current contributing to generation of force applied in the X direction to the carrier 101 out of the current flowing in the coil 202. The symbol Id denotes d-axis current that is current contributing to generation of force applied in the Z direction to the carrier 101 out of the current flowing in the coil 202. The symbol Fq denotes the magnitude of force applied in the X direction to the carrier 101 and the magnets 103. The symbol Fd denotes the magnitude of force applied in the Z direction to the carrier 101 and the magnets 103. The symbol Cq denotes the magnitude of force in the X direction generated per unit q-axis current. The symbol Cd denotes the magnitude of force in the Z direction generated per unit d-axis current. The symbol Cq is a thrust constant in the X direction. The symbol Cd is a thrust constant in the Z direction. Furthermore, the following Equation (2) is defined, where the phase is θ.

θ=360 Q/λ (2)

Then, Iq and Id are expressed by the following Equations (3) and (4), respectively.

Iq=Iu sin(θ)+Iv sin(θ+120°)+Iw sin(θ+240°) (3)

Id=Iu cos(θ)+Iv cos(θ+120°)+Iw cos(θ+240°) (4)

Further, Fq and Fd are expressed by the following Equations (5) and (6), respectively. Fq and Fd are electromagnet force applied to the magnets 103 by the coil 202 of the coil unit 210.

Cq Iq=Fq (5)

Cd Id=Fd (6)

For example, as illustrated in FIG. 2, when the origin O of the transport path and the center Os of the carrier 101 are matched, Q and θ are 0 as indicated in the following Equation (7), respectively.

Q=θ=0 (7)

A case where the origin O and the center Os are matched is considered as an example, and in this case, Equations (3) and (4) can be modified as the following Equations (3-1) and (4-1), respectively.

Iq=Iu 0+Iv √3/2+Iw (−√3/2) (3-1)

Id=Iu 1+Iv (−1/2)+Iw (−1/2) (4-1)

In the above example, a case where a current vector expressed by the following Equation (8) as the current vector (Iu, Iv, Iw) is applied to the coil unit 210 is considered.

(Iu, Iv, Iw)=(−1.0[A], 0.5[A], 0.5 [A]) (8)

In such a case, Iq and Id are calculated as the following Equations (3-2) and (4-2), respectively.

Iq=−1.0 0+0.5 √3/2 +0.5 (−√3/2)=0 [A] (3-2)

Id=−1.0 1+0.5 (−1/2)+0.5 (−1/2)=−3/2 [A] (4-2)

Herein, when Cq is 20√3 [N/A] and Cd is 20 [N/A], (Fq, Fd) is as the following Equation (9).

(Fq, Fd)=(0 [N], −30 [N]) (9)

When the Z direction is the reference, Fd is generated in the same direction as the gravity.

Next, a case where a current vector expressed by the following Equation (10) in which the phase has been shifted by 90 degrees is applied to the coil unit 210 is considered.

(Iu, Iv, Iw)=(0 [A], √3/2 [A], −√3/2 [A]) (10)

Then, Iq and Id are calculated as the following Equations (3-3) and (4-3), respectively.

Iq=0 1+(√3/2)+(−√3/2)+(−√3/2) (−√3/2)=3/2 [A] (3-3)

Id=0 1+(√3/2) (−1/2)+(−29 3/2) (−1/2)=0 [A] (4-3)

Herein, when Cq is 20√3 [N/A] and Cd is 20 [N/A], (Fq, Fd) is as the following Equation (11).

(Fq, Fd)=(30√3 [N], 0 [N]) (11)

When the X direction is the reference, Fq is generated in the transport direction. That is, even with the same position of the carrier 101, it is possible to control the force Fq in the X direction and the force Fd in the Z direction by changing the phase of current to be applied. The coil controller 302, which is a control apparatus, can control the force Fq in the X direction and the force Fd in the Z direction working on the carrier 101 by changing the value and the phase of current applied to the coil unit 210.

In the transport system 1 using the linear motor illustrated in FIG. 1 to FIG. 4B, the force Fq in the transport direction (X direction) is increased by supplying the q-axis current Iq, and the force Fd in the Z direction, which is the orthogonal direction to the coil 202, is increased by supplying the d-axis current Id.

In the present embodiment, it is possible to control the orientation of the force Fd in the Z direction applied to the carrier 101 in accordance with the manner to transport the carrier 101. That is, it is possible to change the orientation of the force Fd in the Z direction for a case of transporting the carrier 101 as with the first embodiment and a case of transporting the carrier 101 as with the second embodiment, respectively.

First, when the carrier 101 is transported such that the top faces of the magnets 103 are located below the equilibrium position P1 as with the first embodiment, the d-axis current is supplied to apply the force Fd to the carrier 101 in the same direction as the gravity to perform transportation. By performing transportation with such control, since the bottoms 108b of the rotary members 108 of the carrier 101 are pushed against the lower-side auxiliary members 205b, the position of the carrier 101 is stabilized. With the stabilized position, since the gap G2 between the rotary member 108 and the auxiliary member 205 can be smaller at the initial adjustment, the carrier 101 can be transported near the equilibrium position P1. By transporting the carrier 101 near the equilibrium position P1 where the magnetic attractive force Fm and the gravity Fg are balanced, it is possible to reduce the force applied to the rotary members 108 or the auxiliary members 205, and it is possible to reduce generation of debris that is a contaminant in the sliding portion thereof. Furthermore, since the force Fd is continued to be applied in the Z direction, the position of the carrier 101 is stabilized, and as a result, the workpiece 102 can be processed at high accuracy.

On the other hand, when the carrier 101 is transported with the top faces of the magnets 103 being at a position above the equilibrium position P1 as with the second embodiment, the sign of the d-axis current Id is changed to be opposite to the case of transportation as with the first embodiment. This causes the direction in which the force Fd is always applied to the carrier 101 to be opposite to the gravity. By performing transportation with such control, since the tops 108a of the rotary members 108 of the carrier 101 are pushed against the upper-side auxiliary members 205a, the same advantageous effect as described above can be obtained.

Note that, with respect to the d-axis current Id and the q-axis current Iq, the maximum current that can be supplied by the coil controller 302 is typically predetermined, respectively. Thus, the coil controller 302 can control the direction of generated force by changing the phase of current. That is, by changing the phase of current, the coil controller 302 can change the ratio of divided current amounts in accordance with the force controlled in the Z direction and the force controlled in the X direction.

For example, when the thrust required in the transport direction is small, since small q-axis current is enough, it is possible to increase the ratio of amount divided into the d-axis current Id and perform transportation while pushing the rotary members 108 against the auxiliary members 205. If transportation with pushing in one direction can be performed, the carrier 101 may overlap the equilibrium position P1.

Further, in the present embodiment, when the weight of the carrier 101 changes, it is possible to perform stable transport of the carrier 101 by controlling the d-axis current. For example, when an idle drive operation without the workpiece 102 loaded is performed or when only some of the carriers 101 are modified when the plurality of carriers 101 are transported, the carriers 101 having different weights may be mixed.

For example, a case where the carrier 101 whose weight is reduced during transportation of the plurality of carriers 101 is mixed is considered. Since the weight of the lightened carrier 101 is smaller, the equilibrium position P1 where the magnetic attractive force Fm and the gravity Fg are balanced moves to a position that is lower in the lightened carrier 101 than in the not-lightened carrier 101. In FIG. 4A, adjustment is performed so that the position P3 of the top face of the magnets 103 is lower than the equilibrium position P1. In the lightened carrier 101, however, since the equilibrium position P1 moves to a lower position, the position P3 of the top faces of the magnets 103 may be higher. Due to the position P3 of the top faces of the magnets 103 being higher than the equilibrium position P1, in an extreme case, the heavy carrier 101 will be transported at the position of FIG. 4B, and the light carrier 101 will be transported at the position of FIG. 4A. In such a way, the height during transportation may differ for the transported carriers 101. Transportation with the carriers 101 of different heights will cause different periods of time required for a process applied on the workpiece 102 from an external apparatus, and this may result in malfunction such as an inability of maintaining a certain quality. Further, in a case of the carrier 101 having a slightly lighter weight, the carrier 101 may have an unstable position in the Z direction in the gap G2 and may travel unstably.

In these cases, it is possible to transport the carrier 101 stably by controlling the d-axis current to flow so as to push the carrier 101 in the direction of the gravity or the direction of magnetic attractive force as described above. That is, according to the present embodiment, even when a plurality of carriers 101 having different weights from each other are mixed, each carrier 101 can be transported more stably with a certain height.

As described above, according to the present embodiment, it is possible to reduce a contaminant generated from a sliding portion of the carrier 101 or the stator 201 without involving an increase in size or an increase in complexity of the apparatus and stably transport the carrier 101.

### Fourth Embodiment

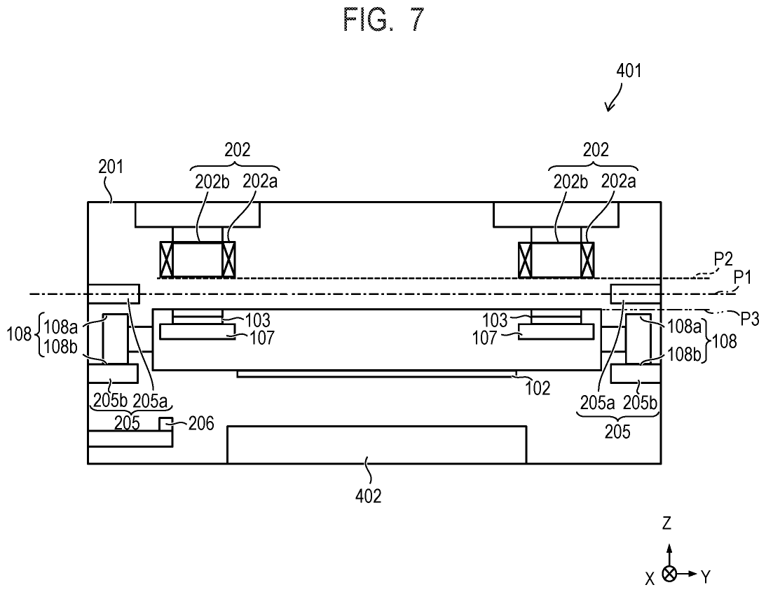

A fourth embodiment of the present invention will be described with reference to FIG. 7. FIG. 7 is a schematic diagram illustrating a configuration including the carrier 101 and the stator 201 in the transport system 1 according to the present embodiment when viewed from the X direction. Note that the same components as those in the first to third embodiments described above are labeled with the same references, and the description thereof will be omitted or simplified.

The basic configuration of the transport system 1 according to the present embodiment is the same as the configuration of the transport system 1 according to the first or second embodiment illustrated in FIG. 1 to FIG. 6B. The transport system 1 according to the present embodiment controls the d-axis current Id for applying the force Fd in the Z direction by utilizing a result of detecting the position in the Z direction of the carrier 101 from a sensor when applying the force Fd in the Z direction to the carrier 101 according to the third embodiment. The transport system 1 according to the present embodiment further has a sensor 206 that detects the position in the Z direction of the carrier 101 in addition to the configuration of the transport system 1 according to the first or second embodiment.

As illustrated in FIG. 7, in the transport system 1 according to the present embodiment, the sensor 206 is attached and installed to the stator 201. The sensor 206 functions as a detection unit that detects the position in the Z direction of the carrier 101, that is, the height of the carrier 101. Specifically, for example, the sensor 206 is a switch such as a photo-switch, a magnetic switch, or the like that detects whether the position in the Z direction of the carrier 101, that is, the height of the carrier 101 is less than or equal to a predetermined threshold or exceeds the threshold, for example. Further, for example, the sensor 206 may be a position sensor such as a photo-sensor, a magnetic sensor, an eddy current sensor, or the like that continuously detects the position in the Z direction of the carrier 101, for example.

The sensor 206 transmits a detection signal indicating a detection result regarding the position in the Z direction of the carrier 101 to the coil controllers 302. Each coil controller 302 controls the d-axis current Id used for applying force in the Z direction to the carrier 101 based on a detection signal received from the sensor 206, which is a detection result from the sensor 206. Note that control of the d-axis current Id based on a detection signal may be performed by another control apparatus such as the integration controller 301, a dedicated controller, or the like instead of the coil controllers 302.

In the present embodiment, it is possible to control the d-axis current Id used for applying the force Fd in the Z direction to the carrier 101 in accordance with the manner to transport the carrier 101. That is, it is possible to change the control of the d-axis current between the case of transporting the carrier 101 as with the first embodiment and the case of transporting the carrier 101 as with the second embodiment.

First, in the first embodiment, the carrier 101 is transported such that the top faces of the magnets 103 are below the equilibrium position P1. Herein, the switch described above is installed as the sensor 206. In such a case, in response to the detection signal from the sensor 206 indicating that the height of the carrier 101 exceeds a threshold, the coil controller 302 supplies the d-axis current Id to control the force Fd in the Z direction and performs control of pushing the carrier 101 in the direction of the gravity Fg. That is, the coil controller 302 controls the d-axis current Id so as to push the bottom 108b of the rotary member 108 against the lower-side auxiliary member 205b.

On the other hand, in the second embodiment, the carrier 101 is transported such that the top faces of the magnets 103 are above the equilibrium position P1. Herein, the switch described above is installed as the sensor 206. In such a case, in response to the detection signal from the sensor 206 indicating that the height of the carrier 101 is less than or equal to a certain threshold, the coil controller 302 supplies the d-axis current to control force in the Z direction and performs control of pushing the carrier 101 in the direction of the magnetic attractive force Fm. That is, the coil controller 302 controls the d-axis current Id so as to push the top 108a of the rotary member 108 against the upper-side auxiliary member 205a.

In such a way, the coil controller 302 controls the d-axis current Id so as to push the rotary member 108 of the carrier 101 against the lower-side auxiliary member 205b or the upper-side auxiliary member 205a based on the height of the carrier 101 detected by the sensor 206. In the present embodiment, in both the transport manners described above, it is possible to realize stable transportation with less unstable movement in the Z direction by transporting the carrier 101 while pushing the carrier 101 in accordance with the position in the Z direction of the carrier 101.

Further, when the position sensor such as a photo-sensor, an eddy current sensor, or the like as described above is installed as the sensor 206, the coil controller 302 can control the d-axis current Id based on the continuous detection value of the positions in the Z direction of the carrier 101. Therefore, the coil controller 302 can control the d-axis current Id at high accuracy and thus can supply the d-axis current Id if necessary during transportation of the carrier 101. In such a case, since it is no longer necessary to continue to supply the d-axis current all the time, energy efficiency can be improved. Therefore, heat generation of the coils 202 or the coil controller 302 can be reduced.

As described above, according to the present embodiment, it is possible to reduce a contaminant generated from a sliding portion of the carrier 101 or the stator 201 without involving an increase in size or an increase in complexity of the apparatus and stably transport the carrier 101.

### Modified Embodiments

The present invention is not limited to the embodiments described above, and various modifications are possible. For example, although the configuration in which the rotary members 108 are installed on the carrier 101 side and the auxiliary members 205 are installed on the stator 201 side has been described as examples in the above embodiments, the present invention is not limited thereto. The same advantageous effects as described above can be obtained even when the auxiliary members 205 are installed on the carrier 101 side and the rotary members 108 are installed on the stator 201 side in contrast to the configuration of the embodiments described above. In such a case, a plurality of rotary members 108 may be installed so as to be aligned along the transport path on the stator 201 side. As described above, the carrier 101 has one of the rotary member 108 and the auxiliary member 205, and the stator 201 has the other of the rotary member 108 and the auxiliary member 205.

Further, although the case where the transport path on which the carrier 101 is transported in one direction is formed of the stator 201 has been described as examples in the above embodiments, the present invention is not limited thereto. As a transport path on which the carrier 101 is transported, another type of transport paths may be formed of the stator 201, such as a transport path on which the carrier 101 reciprocates, a transport path on which the carrier 101 circulates, or the like, for example.

Further, although the case where a single coil controller 302 is connected to each coil unit 210 has been described as examples in the above embodiments, the present invention is not limited thereto. The connection between the coil controllers 302 and the coil units 210 can be changed as appropriate so that a single coil controller 302 can control a plurality of coil units 210.

Further, although the case where each coil unit 210 is formed of a set of three coils 202 has been described as examples in the above embodiments, the present invention is not limited thereto. The number of coils 202 forming the coil unit 210 can be changed as appropriate.

Further, although the case where the integration controller 301 is provided separately from the coil controllers 302 has been described as examples in the above embodiments, the present invention is not limited thereto. The coil controller 302 can have a whole or a part of the function of the integration controller 301 and can also have a function of controlling the overall transport system 1. The functions of the integration controller 301 and the coil controller 302 may be implemented by one or a plurality of control apparatuses.

Further, although the case where the encoders 204 are connected to the coil controller 302 has been described as examples in the above embodiments, the present invention is not limited thereto. The encoder 204 may be connected to and controlled by a controller separately provided and dedicated to the encoder 204.

### Other Embodiments

Embodiments of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiments and/or that includes one or more circuits (e.g., application specific integrated circuit (ASIC)) for performing the functions of one or more of the above-described embodiments, and by a method performed by the computer of the system or apparatus by, for example, reading out and executing the computer executable instructions from the storage medium to perform the functions of one or more of the above-described embodiments and/or controlling the one or more circuits to perform the functions of one or more of the above-described embodiments. The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2020-018350, filed Feb. 5, 2020, which is hereby incorporated by reference herein in its entirety.

What is claimed is:

1. A transport system comprising:
a stator having a plurality of coils arranged along a transport direction, wherein each of the plurality of coils includes a winding and a core; and
a mover having a plurality of magnets arranged so as to face the plurality of coils and configured to move in the transport direction by electromagnetic force generated between the plurality of coils and the magnet,
wherein the stator has one of a first transport member and a second transport member that guide, in the transport direction, the mover that is moving,
wherein the first transport member includes an upper-side transport member and a lower-side transport member installed to be located above and below the second transport member, respectively,
wherein the mover has the other of the first transport member and the second transport member, and a transport position of the mover is adjusted so that an upper face of at least one magnet is located below or above an equilibrium position where magnetic attractive force generated between the core and the magnet and gravity working on the mover are balanced with each other, and
wherein the mover is transported in a state where the second transport member is in contact with the lower-side transport member or the upper-side transport member in accordance with the transport position.

2. The transport system according to claim 1,
wherein the stator has the first transport member,
wherein the mover has the second transport member,
wherein the transport position of the mover is adjusted such that the upper face of the magnet is located below the equilibrium position, and
wherein the mover is transported in a state where the second transport member is in contact with the lower-side transport member.

3. The transport system according to claim 2, wherein a first gap formed between a bottom of the second transport member and the lower-side transport member is smaller than a second gap formed between the core and the magnet.

4. The transport system according to claim 1,
wherein the stator has the first transport member,
wherein the mover has the second transport member,
wherein the transport position of the mover is adjusted so that the upper face of the magnet is located above the equilibrium position, and
wherein the mover is transported in a state where the second transport member is in contact with the upper-side transport member.

5. The transport system according to claim 4, wherein a first gap formed between an upper portion of the second transport member and the upper-side transport member is smaller than a second gap formed between the core and the magnet.

6. The transport system claim 1, wherein the plurality of coils are arranged above the magnet and arranged to be able to face the magnets.

7. The transport system according to claim 1,
wherein the first transport member is a rail-like member, and
wherein the second transport member is a rotary member that rotates while being in contact with the first transport member.

8. The transport system according to claim 1,
wherein the second transport member includes a plurality of second transport members, and
wherein all or some of the plurality of second transport members are in contact with the lower-side transport member or the upper-side transport member.

9. The transport system according to claim 1 further comprising a control apparatus that supplies current to the coil to generate force in a direction to cancel gravity working on the mover, causes the second transport member to be pressed against the lower-side transport member or the upper-side transport member, and moves the mover in the transport direction.

10. The transport system according to claim 9 further comprising a detection unit that detects a height of the mover,
wherein the control apparatus controls the current based on a detection result from the detection unit.

11. A transport system comprising:
a stator having a plurality of coils arranged along a transport direction; and
a mover having a plurality of magnets arranged so as to face the plurality of coils,
wherein the stator has one of a first transport member and a second transport member that guide, in the transport direction, the mover that is moving,
wherein the first transport member includes an upper-side transport member and a lower-side transport member installed to be located above and below the second transport member, respectively, and
wherein the mover has the other of the first transport member and the second transport member, and
the transport system further comprising a control apparatus that supplies current to the coil, generates force in the direction to cancel the gravity working on the mover, causes the second transport member to press against the lower-side transport member or the upper-side transport member, and moves the mover in the transport direction.

12. A processing system comprising:
the transport system according to claim 1; and
a process apparatus that performs processing on a workpiece transported by the mover.

13. An article manufacturing method for manufacturing an article by using the processing system according to claim 12, the article manufacturing method comprising steps of:
transporting the workpiece by using the mover; and
performing, by using the process apparatus, the processing on the workpiece transported by the mover.
